(19) United States
(12) Patent Application Publication
(10) Pub. No.: US 2024/0090263 A1
(43) Pub. Date: Mar. 14, 2024

(54) DISPLAY PANEL

(71) Applicant: Samsung Display Co., Ltd., Yongin-si (KR)

(72) Inventors: Jeonggi Kim, Yongin-si (KR); Sungwook Kim, Yongin-si (KR); Taesik Kim, Yongin-si (KR); Youngwoo Park, Yongin-si (KR); Jeongsoo Lee, Yongin-si (KR); Jina Lee, Yongin-si (KR); Wansoon Im, Yongin-si (KR); Seongbaik Chu, Yongin-si (KR)

(73) Assignee: Samsung Display Co., Ltd., Yongin-si (KR)

(21) Appl. No.: 18/347,096

(22) Filed: Jul. 5, 2023

(30) Foreign Application Priority Data
Sep. 8, 2022 (KR) 10-2022-0114491

(51) Int. Cl. H10K 59/121; H10K 59/131

(52) U.S. Cl. CPC H10K 59/1213; H10K 59/1216; H10K 59/131

(57) ABSTRACT

A display panel includes a driving voltage line, an organic light-emitting diode, a driving transistor electrically connected between the driving voltage line and the organic light-emitting diode, a data write transistor electrically connected between the driving transistor and a data line, a first voltage line extending in a first direction, a first transistor electrically connected between the driving transistor and the first voltage line, a first vertical voltage line extending in a second direction perpendicular to the first direction and electrically connected to the first voltage line, and a second transistor electrically connected between the driving transistor and the driving voltage line.

### CROSS-REFERENCE TO RELATED APPLICATION(S)

This application claims priority to Korean Patent Application No. 10-2022-0114491 under 35 U.S.C. § 119, filed on Sep. 8, 2022, in the Korean Intellectual Property Office, the entire contents of which are incorporated herein by reference.

### BACKGROUND

### 1. Technical Field

Embodiments relate to a display panel and a display apparatus including the same.

### 2. Description of the Related Art

Recently, the usage of display apparatuses has diversified. Moreover, display apparatuses have become thinner and lighter, and thus, the usage thereof has expanded.

As display apparatuses are used for various purposes, there are various methods of designing the shapes of display apparatuses, and functions which may be connected to or associated with the display apparatuses have increased.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments include a display apparatus with improved display quality. However, this objective is an example and does not limit the scope of the disclosure.

Additional aspects will be set forth in part in the description which follows and, in part, will be apparent from the description, or may be learned by practice of the embodiments of the disclosure.

According to embodiments, a display panel may include a driving voltage line, an organic light-emitting diode, a driving transistor electrically connected between the driving voltage line and the organic light-emitting diode, a data write transistor electrically connected between the driving transistor and a data line, a first voltage line extending in a first direction, a first transistor electrically connected between the driving transistor and the first voltage line, a first vertical voltage line extending in a second direction perpendicular to the first direction and electrically connected to the first voltage line, and a second transistor electrically connected between the driving transistor and the driving voltage line.

The first transistor may be electrically connected between a first node to which the driving transistor and the second transistor are electrically connected and the first voltage line, and the data write transistor may be electrically connected between the first node and the data line.

The display panel may further include a second voltage line extending in the first direction, a third transistor electrically connected between the organic light-emitting diode and the second voltage line, and a second vertical voltage line extending in the second direction and electrically connected to the second voltage line.

The display panel may further include a gate line that applies a control signal to a gate of the first transistor and a gate of the third transistor and extending in the first direction.

The display panel may further include a third voltage line extending in the first direction, a fourth transistor electrically connected between a gate of the driving transistor and the third voltage line, and a third vertical voltage line extending in the second direction and electrically connected to the third voltage line.

The fourth transistor may include a pair of sub-transistors electrically connected in series, and the display panel may further include a capacitor electrically connected between the driving voltage line and a node between the pair of sub-transistors.

The display panel may further include a fifth transistor electrically connected between a gate of the driving transistor and a second node, the second node being between the driving transistor and the organic light-emitting diode.

The fifth transistor may include a pair of sub-transistors electrically connected in series, and the display panel may further include a capacitor electrically connected between the driving voltage line and a node between the pair of sub-transistors.

The display panel may further include a fourth transistor electrically connected between a gate of the driving transistor and a third voltage line and including a pair of sub-transistors electrically connected in series, a fifth transistor electrically connected between the gate of the driving transistor and a node, the node being between the driving transistor and the organic light-emitting diode, the fifth transistor including a pair of sub-transistors electrically connected in series, a first capacitor electrically connected between the driving voltage line and the gate of the driving transistor, a second capacitor electrically connected between the driving voltage line and a node between the pair of sub-transistors of the fourth transistor, and a third capacitor electrically connected between the driving voltage line and a node between the pair of sub-transistors of the fifth transistor.

The driving voltage line may include a first driving voltage line extending in the first direction and a second driving voltage line extending in the second direction and electrically connected to the first driving voltage line.

According to embodiments, a display panel may include a substrate including a display area and a peripheral area surrounding the display area, a plurality of pixel circuits disposed in pixel areas where a plurality of rows and a plurality of columns of pixels in the display area cross each other, a plurality of first voltage lines extending in a row direction, each of the plurality of first voltage lines being disposed in a corresponding row of the rows, and a plurality of first vertical voltage lines extending in a column direction, disposed at intervals of a first number of columns, and electrically connected to the plurality of first voltage lines. Each of the plurality of pixel circuits may include a driving transistor, a data write transistor electrically connected between the driving transistor and a data line, a first transistor electrically connected between the driving transistor and a first voltage line disposed in a corresponding row, from among the plurality of first voltage lines; and a second transistor electrically connected between the driving transistor and a driving voltage line.

The display panel may further include a first voltage supply line disposed in the peripheral area, wherein the plurality of first voltage lines and the first vertical voltage lines may be electrically connected to the first voltage supply line in the peripheral area.

The display panel may further include a plurality of second voltage lines extending in the row direction, each of the plurality of second voltage lines being disposed in a corresponding row of the rows and a plurality of second vertical voltage lines extending in the column direction, disposed at intervals of a second number of columns, and electrically connected to the plurality of second voltage lines, wherein each of the plurality of pixel circuits may further include a third transistor electrically connected between a display element and a second voltage line disposed in a corresponding row from among the plurality of second voltage lines.

The display panel may further include a second voltage supply line disposed in the peripheral area, wherein the plurality of second vertical voltage lines may be electrically connected to the second voltage supply line in the peripheral area.

The first number may be greater than the second number, one of the plurality of first vertical voltage lines may be disposed between a pair of adjacent pixel areas, and one of the plurality of second vertical voltage lines may be disposed between another pair of adjacent pixel areas.

The display panel may further include a plurality of third voltage lines extending in the row direction, each of the plurality of third voltage lines being disposed in a corresponding row of the rows and a plurality of third vertical voltage lines extending in the column direction, disposed at intervals of the first number of columns, and electrically connected to the plurality of third voltage lines, wherein each of the plurality of pixel circuits may further include a fourth transistor electrically connected between a gate of the driving transistor and a third voltage line disposed in a corresponding row from among the plurality of third voltage lines.

The display panel may further include a third voltage supply line disposed in the peripheral area, wherein the plurality of third vertical voltage lines may be electrically connected to the third voltage supply line in the peripheral area.

One of the plurality of first vertical voltage lines may be disposed between a pair of adjacent pixel areas, and one of the plurality of third vertical voltage lines may be disposed between another pair of adjacent pixel areas.

Each of the pixel circuits may include a fifth transistor electrically connected between the gate of the driving transistor and a second node, the second node being between the driving transistor and an organic light-emitting diode, a first capacitor including a first electrode including the gate of the driving transistor and a second electrode above the first electrode, a second capacitor including a third electrode electrically connected to a semiconductor layer of the fifth transistor and a fourth electrode above the third electrode, and a third capacitor including a fifth electrode electrically connected to a semiconductor layer of the fourth transistor and a sixth electrode above the fifth electrode.

The third electrode of the second capacitor and the fifth electrode of the third capacitor may each include a semiconductor material, and the second electrode of the first capacitor, the fourth electrode of the second capacitor, and the sixth electrode of the third capacitor may be integral with each other and may be electrically connected to the driving voltage line.

It is to be understood that the embodiments above are described in a generic and explanatory sense only and not for the purpose of limitation, and the disclosure is not limited to the embodiments described above.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display panel according to an embodiment;

FIGS. 2A and 2B are schematic diagrams of an equivalent circuit of a pixel according to an embodiment;

FIGS. 3A to 4B are diagrams showing an example of a light waveform obtained by measuring brightness of a display apparatus;

FIGS. 5A and 5B are schematic diagrams showing a connection relationship of signal lines arranged in a display area and a peripheral area;

FIGS. 6 to 16 are schematic layout diagrams illustrating devices of a pixel circuit for each layer,

FIG. 17 is a schematic cross-sectional view of a region taken along line II-II′ of FIG. 14;

FIG. 18 is a schematic plan view of a display panel according to an embodiment; and

FIGS. 19A and 19B are schematic diagrams of an equivalent circuit of a pixel according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional layer such as an adhesion layer or an additional element such as an adhesion element therebetween.

It will be understood that the terms “connected to” or “coupled to” may refer to a physical, electrical and/or fluid connection or coupling, with or without intervening elements.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the embodiments hereinafter, the expression “plan view” indicates a view when an object is seen downwardly, and the expression “cross-sectional view” indicates a view when an object, which is vertically taken, is seen from the lateral perspective.

In the embodiments hereinafter, an x direction, a y direction and a z direction are not limited to three axes of the rectangular coordinate system, and may be interpreted in a broader sense. For example, the x direction, the y direction, and the z direction may be perpendicular to one another, or may represent different directions that are not perpendicular to one another.

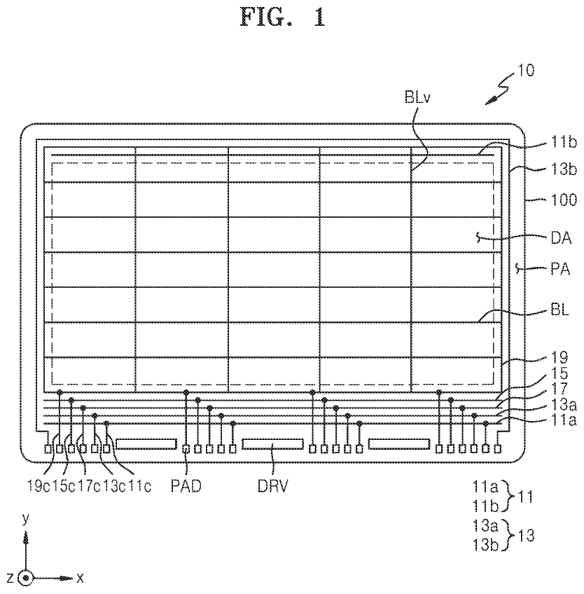

FIG. 1 is a schematic plan view of a display panel 10 according to an embodiment.

A display apparatus may include the display panel 10, and a cover window (not shown) protecting the display panel 10 may further be arranged above the display panel 10.

The display panel 10 may have a rectangular shape in a plan view as illustrated in FIG. 1. A pair of sides of two pairs of sides of a rectangle may have greater lengths than the other pair of sides. In the display panel 10 illustrated in FIG. 1, a first direction (an x direction, a row direction) may be an extension direction of long sides, a second direction (a y direction, a column direction) may be an extension direction of short sides, and a direction perpendicular to the extension directions of the long sides and the short sides may be indicated as a third direction (a z direction). At least one corner of the display panel 10 may have a round shape.

Referring to FIG. 1, the display panel 10 may include a display area DA in which multiple pixels are arranged (disposed) and a peripheral area PA outside the display area DA. The peripheral area PA may be a type of non-display area in which pixels are not arranged. The display area DA may be entirely surrounded by the peripheral area PA. Various elements included in the display panel 10 may be arranged on a substrate 100. Thus, it may be understood that the substrate 100 may include the display area DA and the peripheral area PA.

The display panel 10 may provide an image by using light emitted from the pixels arranged in the display area DA. The pixel may emit, for example, red, green, or blue light. In an embodiment, the pixel may emit red, green, blue, or white light. The pixel may include a display element, and the display element may include an organic light-emitting diode. The display element may be connected to a pixel circuit configured to drive the display element. Through the light emitted from the pixels, images may be provided.

Various lines configured to transmit electrical signals to be applied to the display area, the electrical signals being configured to drive the pixel circuit, pads PAD connected to the lines and configured to transmit signals applied from the outside to the lines, and a driver DRV may be arranged in the peripheral area PA. Various lines configured to transmit the electrical signals may include a driving voltage supply line 11, a common voltage supply line 13, a first initialization voltage supply line 15, a second initialization voltage supply line 17, and a bias voltage supply line 19.

The driving voltage supply line 11 may include a first driving voltage supply line 11a and a second driving voltage supply line 11b. The common voltage supply line 13 may include a first common voltage supply line 13a and a second common voltage supply line 13b. The first driving voltage supply line 11a may be connected to the pad PAD through a connection line 11c and may extend in the x direction below the display area DA. The second driving voltage supply line 11b may extend in the x direction above the display area DA. The first common voltage supply line 13a may be connected to the pad PAD through a connection line 13c and may extend in the x direction below the display area DA. The second common voltage supply line 13b may be connected to the pad PAD and may have a loop shape having an open side to partially surround the display area DA.

The first initialization voltage supply line 15 may be connected to the pad PAD through a connection line 15c and may extend in the x direction below the display area DA. The second initialization voltage supply line 17 may be connected to the pad PAD through a connection line 17c and may extend in the x direction below the display area DA. The bias voltage supply line 19 may be connected to the pad PAD through a connection line 19c and may have a loop shape to surround the display area DA. The bias voltage supply line 19 may be connected to multiple bias voltage lines (also referred to as the horizontal bias voltage lines) BL and multiple vertical bias voltage lines (also referred to as the vertical voltage lines) BLv arranged in the display area DA. Thus, the bias voltage lines BL may have a mesh structure in the display area DA. According to another embodiment, the bias voltage supply line 19 may have a loop shape having an open upper side.

The driver DRV may be formed as a single integrated circuit chip or one or more integrated circuit chips and may be mounted on the substrate 100. The driver DRV may be configured to generate data signals, and the data signals may be transmitted to the pixel circuits of the pixels through a data line of the display area DA. The driver DRV may be configured to generate a control signal to be transmitted to a scan driving circuit (not shown) arranged in the peripheral area PA. The scan driving circuit may be arranged in the peripheral area PA on a left side and/or a right side of the substrate 100, with the display area DA between the peripheral area PA on the left side and the peripheral area PA on the right side of the substrate 100. The scan driving circuit may be overlapped with some of the lines arranged in the peripheral area PA. The scan driving circuit may be configured to generate a scan signal, and the scan signal may be transmitted to the pixel circuits through a scan line of the display area DA.

Hereinafter, an organic light-emitting display apparatus may be described as an example of a display apparatus according to an embodiment. However, the display apparatus according to the disclosure is not limited thereto. According to another embodiment, the display apparatus according to the disclosure may include a display apparatus, such as an inorganic light-emitting display apparatus, an inorganic electro-luminescence (EL) display apparatus, or a quantum dot light-emitting display apparatus. For example, an emission layer of a display element included in the display apparatus may include an organic material or an inorganic material. The display apparatus may include the emission layer and quantum dots located on a path of light emitted from the emission layer.

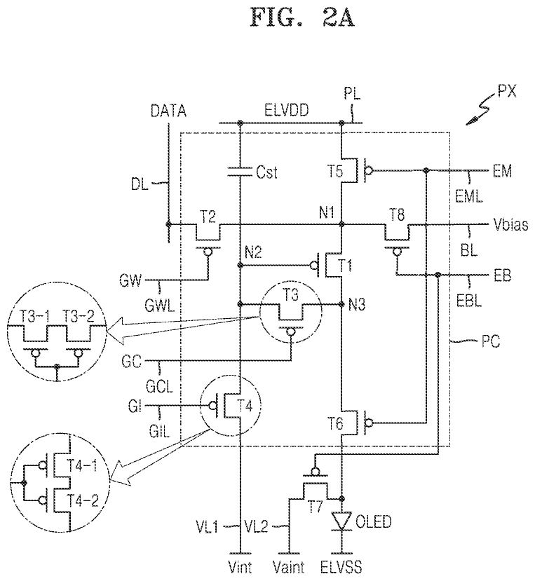

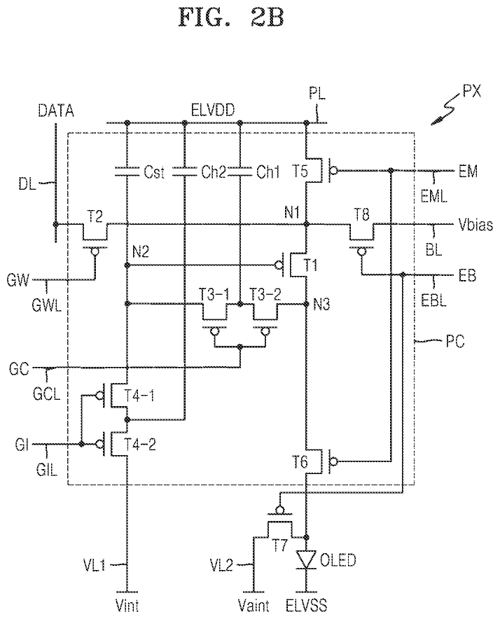

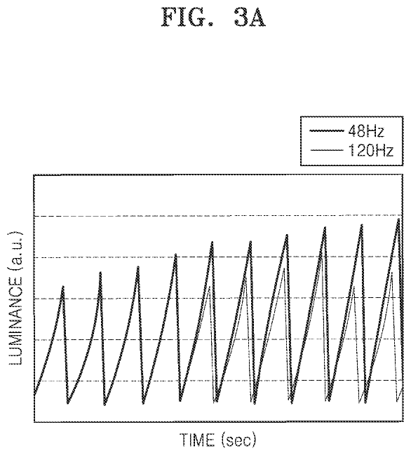

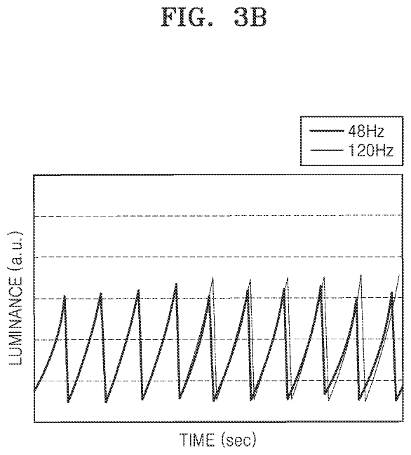

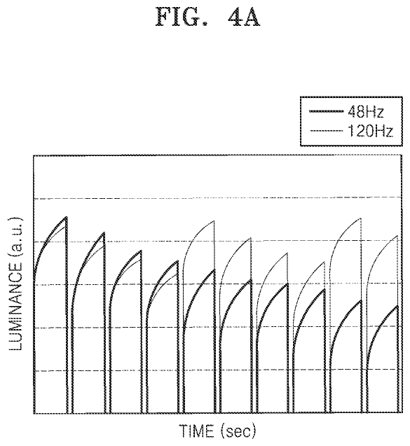

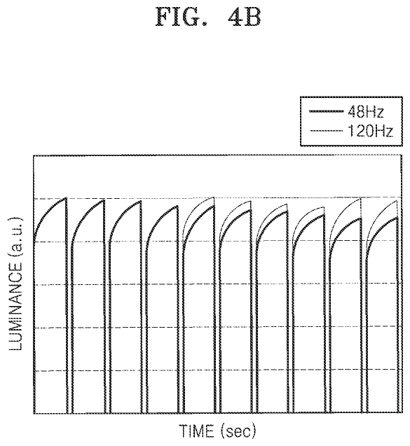

FIGS. 2A and 2B are schematic diagrams of an equivalent circuit of a pixel according to an embodiment. FIGS. 3A to 4B are diagrams showing an example of a light waveform obtained by brightness measurement of a display apparatus. FIGS. 3A to 4B show examples of a luminance change of a light waveform according to different driving frequencies in a display apparatus supporting a variable refresh rate (VRR). Referring to FIG. 2A, a pixel PX may include a pixel circuit PC, and an organic light-emitting diode OLED, which is a display element connected to the pixel circuit PC. The pixel circuit PC may include transistors, for example, first to eighth transistors T1 to T8, a capacitor Cst, and signal lines connected to the first to eighth transistors T1 to T8 and the capacitor Cst. The signal lines may include a data line DL, a first gate line GWL, a second gate line GCL, a third gate line GIL, an emission control line EML, a bias control line EBL, first and second initialization voltage lines VL1 and VL2, a driving voltage line PL, and a bias voltage line BL.

The first gate line GWL, the second gate line GCL, the third gate line GIL, the emission control line EML, and the bias control line EBL may be gate control lines to which a gate signal for controlling transistors to be turned on and turned off is applied. The driving voltage line PL may be configured to transmit a driving voltage ELVDD to the first transistor T1. The driving voltage ELVDD may be a high voltage provided to a pixel electrode (a first electrode or an anode) of an organic light-emitting diode included in each pixel PX. The first initialization voltage line VL1 may be configured to transmit a first initialization voltage Vint for initializing the first transistor T1 to the pixel PX. The second initialization voltage line VL2 may be configured to transmit a second initialization voltage Vaint for initializing the organic light-emitting diode OLED to the pixel PX. The bias voltage line BL may be configured to transmit a bias voltage Vbias to the first transistor T1.

The first transistor T1 may be a driving transistor, and the second to eighth transistors T2 to T8 may be switching transistors. According to a type (an N-type or a P-type) and/or an operation condition of the transistor, a first terminal of each of the first to eighth transistors T1 to T8 may be a source terminal or a drain terminal, and a second terminal of each of the first to eighth transistors T1 to T8 may be a different terminal from the first terminal. For example, in case that the first terminal is the source terminal, the second terminal may be the drain terminal. According to an embodiment, the source terminal and the drain terminal may be interchangeably referred to as a source electrode and a drain electrode, respectively.

The first transistor T1 may be connected between the driving voltage line PL and the organic light-emitting diode OLED. The first transistor T1 may be connected to the driving voltage line PL through the fifth transistor T5 and may be electrically connected to the organic light-emitting diode OLED through the sixth transistor T6. The first transistor T1 may include a gate (also referred to as a gate electrode) connected to a second node N2, a first terminal connected to a first node N1, and a second terminal connected to a third node N3. The first transistor T1 may be configured to receive a data signal according to a switching operation of the second transistor T2 and supply a driving current to the organic light-emitting diode OLED.

The second transistor T2 (a data write transistor) may be connected between the data line DL and the first node N1 and may be connected to the driving voltage line PL through the fifth transistor T5. The first node N1 may be a node to which the first transistor T1 and the fifth transistor T5 are connected. The second transistor T2 may include a gate connected to the first gate line GWL, a first terminal connected to the data line DL, and a second terminal connected to the first node N1 (or the first terminal of the first transistor T1). The second transistor T2 may be configured to be turned on according to a first gate signal GW transmitted through the first gate line GWL and perform a switching operation of transmitting, to the first node N1, a data signal transmitted through the data line DL.

The third transistor T3 (a compensation transistor) may be connected between the second node N2 and the third node N3. The third transistor T3 may be connected to the organic light-emitting diode OLED through the sixth transistor T6. The second node N2 may be a node to which the gate of the first transistor T1 is connected, and the third node N3 may be a node to which the first transistor T1 and the sixth transistor T6 are connected. The third transistor T3 may include a gate connected to the second gate line GCL, a first terminal connected to the second node N2 (or the gate of the first transistor T1), and a second terminal connected to the third node N3 (or the second terminal of the first transistor T1). The third transistor T3 may be configured to be turned on according to a second gate signal GC transmitted through the second gate line GCL and diode-connect the first transistor T1 to compensate for a threshold voltage of the first transistor T1. The third transistor T3 may include a pair of sub-transistors T3- and T3-2 connected in series.

The fourth transistor T4 (a first initialization transistor) may be connected between the second node N2 and the initialization voltage line VL1. The fourth transistor T4 may include a gate connected to the third gate line GIL, a first terminal connected to the second node N2, and a second terminal connected to the first initialization voltage line VL1. The fourth transistor T4 may be configured to be turned on according to a third gate signal GI transmitted through the third gate line GIL and transmit a first initialization voltage Vint to the gate of the first transistor T1 to initialize the gate of the first transistor T1. The fourth transistor T4 may include a pair of sub-transistors T4-1 and T4-2 connected in series.

The fifth transistor T5 (a first emission control transistor) may be connected between the driving voltage line PL and the first node N1. The sixth transistor T6 (a second emission control transistor) may be connected between the third node N3 and the organic light-emitting diode OLED. The fifth transistor T5 may include a gate connected to the emission control line EML, a first terminal connected to the driving voltage line PL, and a second terminal connected to the first node N1. The sixth transistor T6 may include a gate connected to the emission control line EML, a first terminal connected to the third node N3, and a second terminal connected to the pixel electrode of the organic light-emitting diode OLED. The fifth transistor T5 and the sixth transistor T6 may be configured to be simultaneously turned on according to an emission control signal EM received through the emission control line EML, so that driving currents may flow in the organic light-emitting diode OLED.

The seventh transistor T7 (a second initialization transistor) may be connected between the organic light-emitting diode OLED and the second initialization voltage line VL2. The seventh transistor T7 may include a gate connected to the bias control line EBL, a first terminal connected to the second terminal of the sixth transistor T6 and the pixel electrode of the organic light-emitting diode OLED, and a second terminal connected to the second initialization voltage line VL2. The seventh transistor T7 may be configured to be turned on according to a bias control signal EB received through the bias control line EBL and transmit a second initialization voltage Vaint to the pixel electrode of the organic light-emitting diode OLED to initialize the pixel electrode of the organic light-emitting diode OLED. The seventh transistor T7 may be omitted.

The eighth transistor T8 (a bias transistor) may be connected between the first node N1 and the bias voltage line BL. The eighth transistor T8 may include a gate connected to the bias control line EBL, a first terminal connected to the bias voltage line BL, and a second terminal connected to the first node N1. The eighth transistor T8 may be configured to be turned on according to a bias control signal EB received through the bias control line EBL and apply a bias voltage Vbias to the first terminal of the first transistor T1 to pre-configure, for the first terminal of the first transistor T1, an appropriate voltage for a sequential operation of the first transistor T1.

FIG. 3A illustrates a luminance change of a light waveform of a display apparatus including a pixel circuit in which the eighth transistor T8 is omitted, according to a comparative embodiment, and FIG. 3B illustrates a luminance change of a light waveform of a display apparatus including a pixel circuit including the eighth transistor T8, according to an embodiment. As illustrated in FIG. 3A, with respect to the display apparatus including the pixel circuit in which the eighth transistor T8 is omitted, a flicker phenomenon may occur as the luminance is changed (increased) in a low gradation according to time, due to the hysteresis characteristics of the first transistor T1, in case that the display apparatus is driven by a high frequency (120 Hz) and a low frequency (48 Hz). As illustrated in FIG. 3B, by applying the bias voltage Vbias to the first terminal of the first transistor T1 by using the eighth transistor T8, during a high frequency and low frequency driving operation of the display apparatus, the luminance change of the display apparatus in a low gradation according to time may be reduced, and thus, there may be improvement in terms of a flicker phenomenon. By applying the bias voltage Vbias to the first terminal of the first transistor T1 at a holding section between sections for applying data during the low frequency driving operation, a luminance difference between the high frequency driving operation and the low frequency driving operation may be minimized.

The capacitor Cst may include a first electrode and a second electrode. The first electrode may be connected to the gate of the first transistor T1, and the second electrode may be connected to the driving voltage line PL. The capacitor Cst may be configured to store and retain a voltage corresponding to a difference between voltages of the driving voltage line PL and the gate of the first transistor T1, to retain a voltage applied to the gate of the first transistor T1.

According to another embodiment, as illustrated in FIG. 2B, the pixel circuit PC may further include a second capacitor Ch1 and a third capacitor Ch2. The second capacitor Ch1 may be connected between an intermediate node between the sub-transistors T3-1 and T3-2 of the third transistor T3 and the driving voltage line PL. The third capacitor Ch2 may be connected between an intermediate node between the sub-transistors T4-1 and T4-2 of the fourth transistor T4 and the driving voltage line PL.

FIG. 4A illustrates a luminance change of a light waveform of a display apparatus including a pixel circuit in which the second capacitor Ch1 and the third capacitor Ch2 are omitted, according to an embodiment, and FIG. 4B illustrates a luminance change of a light waveform of a display apparatus including a pixel circuit including the second capacitor Ch1 and the third capacitor Ch2, according to an embodiment. As illustrated in FIG. 4A, with respect to the display apparatus including the pixel circuit in which the second capacitor Ch1 and the third capacitor Ch2 are omitted, a phenomenon may occur, whereby the luminance is changed (decreased) in a high gradation according to time due to off-current leakage of the third transistor T3 and the fourth transistor T4 during a high frequency (120 Hz) driving operation and a low frequency (48 Hz) driving operation of the display apparatus. As illustrated in FIG. 4B, by including the second capacitor Ch1 and the third capacitor Ch2, during a high frequency driving operation and a low frequency driving operation of the display apparatus, the luminance change of the display apparatus in a high gradation according to time may be reduced. For example, according to the embodiment of FIG. 4A, an F-value corresponding to a luminance difference in the high gradation between the high frequency driving operation and the low frequency driving operation is 0.104 nit/Hz, and flicker is −50 db. However, according to the embodiment of FIG. 4B, the F-value is reduced to 0.026 nit/Hz, and the flicker is decreased to −61 db. The organic light-emitting diode OLED may include the pixel electrode and an opposite electrode, and the opposite electrode may receive a common voltage ELVSS as shown in FIG. 2A and FIG. 2B. The common voltage ELVSS may be a low voltage provided to the opposite electrode (a second electrode or a cathode) of the organic light-emitting diode OLED. The organic light-emitting diode OLED may receive a driving current I_{OLED} from the first transistor T1 and emit light to display an image.

A driving voltage ELVDD may be applied to the pixel circuits of the pixels PX through the driving voltage line PL connected to the driving voltage supply line 11, and the common voltage ELVSS may be applied to the opposite electrodes of the display elements through the common voltage supply line 13.

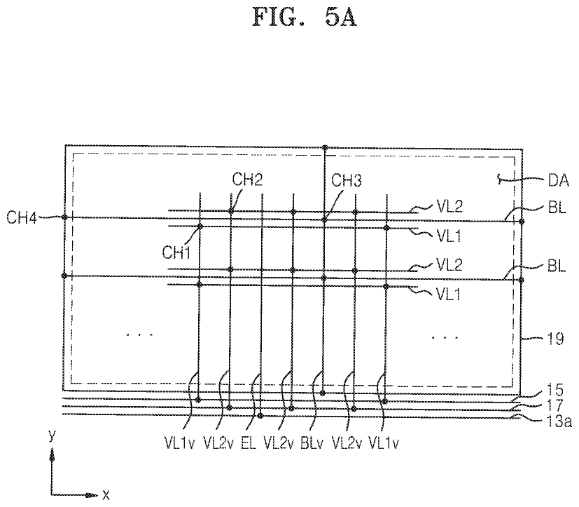

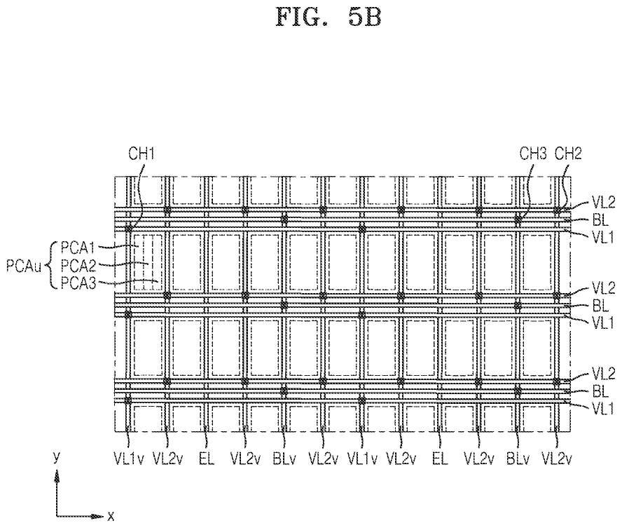

FIGS. 5A and 5B are schematic diagrams showing a connection relationship of signal lines arranged in the display area DA and the peripheral area PA.

As illustrated in FIGS. 5A and 5B, horizontal conductive lines extending in an x direction and vertical conductive lines extending in a y direction may be arranged in the display area DA. The horizontal conductive lines may include the first initialization voltage line VL1, the second initialization voltage line VL2, and the bias voltage line BL. Each of the first initialization voltage line VL1, the second initialization voltage line VL2, and the bias voltage line BL may be arranged for each row. The vertical conductive lines may include a first vertical initialization voltage line VL1v, a second vertical initialization voltage line VL2v, and a vertical bias voltage line BLv.

The first initialization voltage lines VL1 may be electrically connected to the first vertical initialization voltage lines VL1v through a contact hole CH1 to form a mesh structure in the display area DA. The first vertical initialization voltage lines VL1v may be electrically connected to the first initialization voltage supply line 15 of the peripheral area PA through a contact hole. The second initialization voltage lines VL2 may be electrically connected to the second vertical initialization voltage lines VL2v through a contact hole CH2 to form a mesh structure in the display area DA. The second vertical initialization voltage lines VL2v may be electrically connected to the second initialization voltage supply line 17 of the peripheral area PA through a contact hole. The bias voltage lines BL may be electrically connected to the vertical bias voltage lines BLv through a contact hole CH3 to form a mesh structure in the display area DA. The bias voltage lines BL and the vertical bias voltage lines BLvs may be electrically connected to the bias voltage supply line 19 of the peripheral area PA through a contact hole CH4.

A common voltage line EL may further be arranged in the display area DA as one of the vertical conductive lines. An end of the common voltage lines EL may be electrically connected to the first common voltage supply line 13a. Although not shown, another end of the common voltage lines EL may be electrically connected to the second common voltage supply line 13b (FIG. 1). An opposite electrode may be electrically connected to the common voltage lines EL at regular intervals in the display area DA, and the opposite electrode may be electrically connected to the first common voltage supply line 13a and the second common voltage supply line 13b in the peripheral area PA.

Each of the first vertical initialization voltage line VL1v, the second vertical initialization voltage line VL2v, the common voltage line EL, and the vertical bias voltage line BLv may be arranged in the x direction at intervals (e.g., predetermined or selectable intervals). One of the first vertical initialization voltage line VL1v, the second vertical initialization voltage line VL2v, the common voltage line EL, and the vertical bias voltage line BLv may be arranged between a pair of unit pixel areas PCAu adjacent to each other in the x direction. As illustrated in FIG. 5B, the unit pixel area PCAu may include three pixel areas, and each pixel area may be an area where a row and a column of a pixel cross each other and the pixel circuit is arranged.

The unit pixel area PCAu may include a first pixel area PCA1, a second pixel area PCA2, and a third pixel area PCA3. Each of the first pixel area PCA1, the second pixel area PCA2, and the third pixel area PCA3 may be arranged in a column, and thus, one of the first vertical initialization voltage line VL1v, the second vertical initialization voltage line VL2v, the common voltage line EL, and the vertical bias voltage line BLv may be arranged at intervals of three columns adjacent to each other in the x direction.

According to an embodiment, as illustrated in FIG. 5B, the first vertical initialization voltage line VL1v may be arranged at intervals of six unit pixel areas PCAu or intervals of eighteen columns. The second vertical initialization voltage line VL2v may be arranged at intervals of two unit pixel areas PCAu or intervals of six columns. The common voltage line EL may be arranged at intervals of six unit pixel areas PCAu or intervals of eighteen columns. The vertical bias voltage line BLv may be arranged at intervals of six unit pixel areas PCAu or intervals of eighteen columns.

According to an embodiment, the vertical conductive lines may be arranged on different layers from the horizontal conductive lines. Some of the horizontal conductive lines may be arranged on the same layer, and the others may be arranged on the different layers.

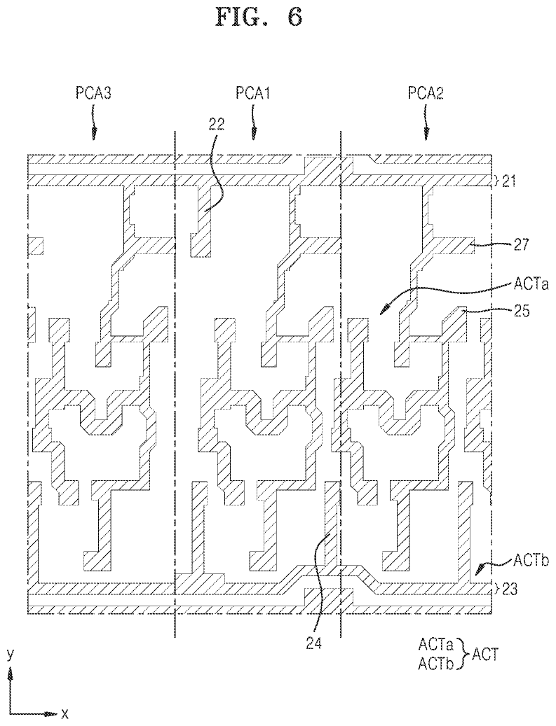

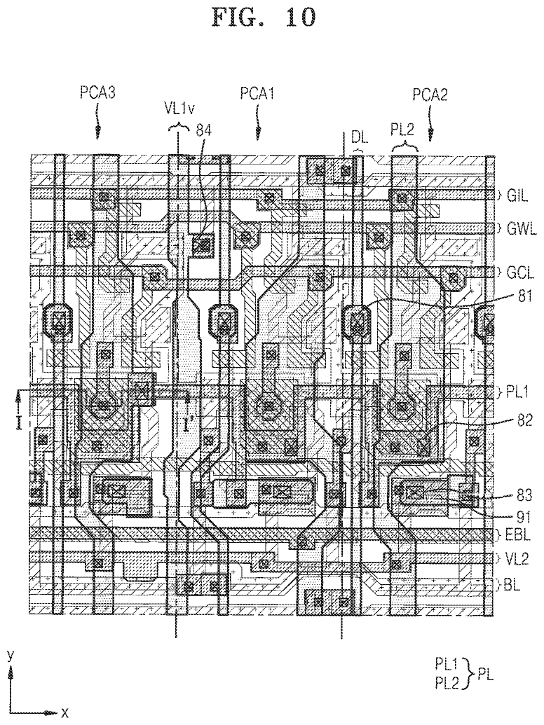

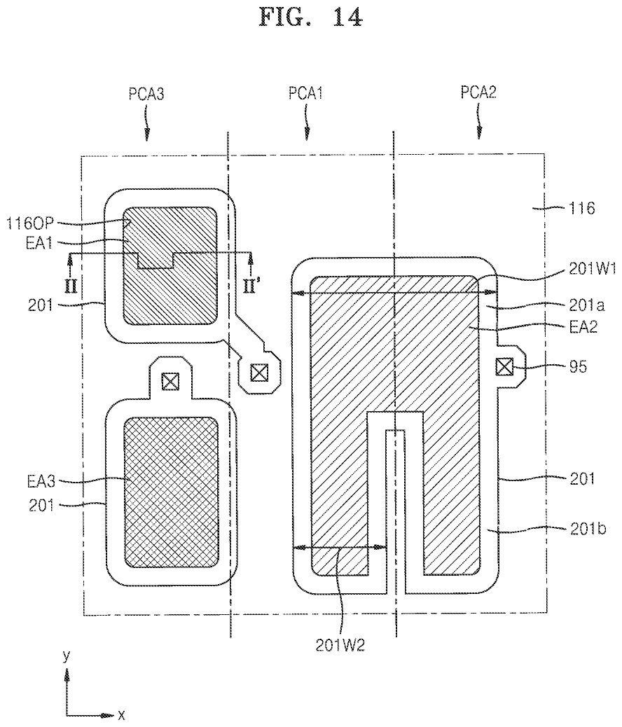

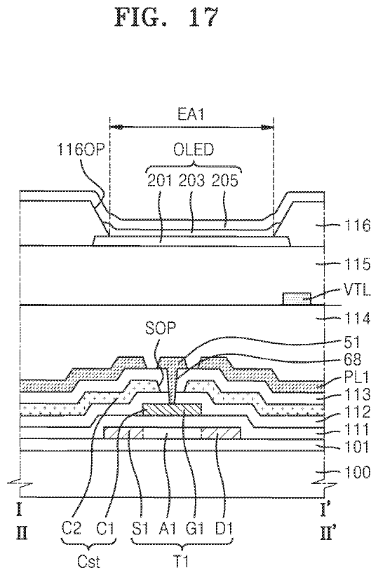

According to a comparative embodiment, in case that only the horizontal conductive lines including the first initialization voltage line VL1, the second initialization voltage line VL2, and the bias voltage line BL are provided, in images, horizontal lines may be visible. According to an embodiment, the horizontal conductive lines and the vertical conductive lines connected thereto may be provided to form a mesh structure, and thus, there may be improvement in terms of ripples of the horizontal lines to decrease the visibility of the horizontal lines in images. FIGS. 6 to 16 are schematic layout diagrams illustrating devices of a pixel circuit for each layer. FIG. 17 is a schematic cross-sectional view of a region taken along line II-II′ of FIG. 14. The region of FIG. 17, taken along line II-II′, may correspond to a region taken along line I-I′ of FIGS. 10 to 13.

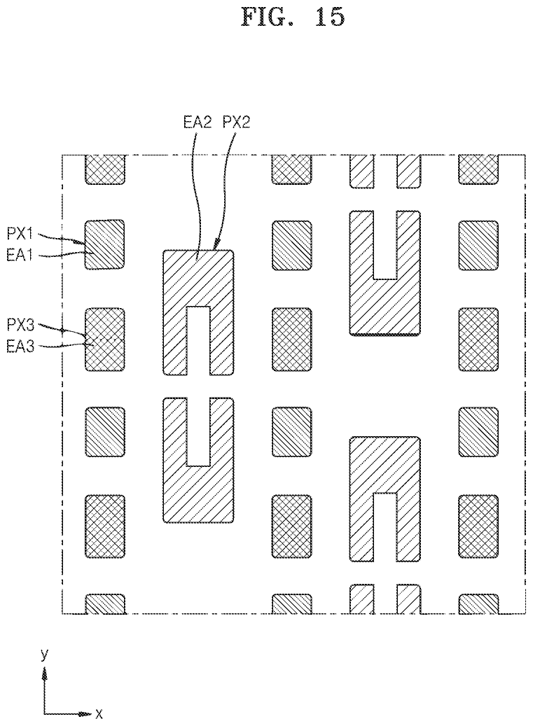

Pixel areas in which rows and columns of pixels cross each other may be defined in the display area DA, and a pixel circuit may be arranged in each pixel area. The layout diagrams of FIGS. 6 to 16 show pixel circuits respectively arranged in the first pixel area PCA1, the second pixel area PCA2, and the third pixel area PCA3 in the same row. A pixel circuit of a first pixel PX1 (FIG. 15) emitting light of a first color may be arranged in the first pixel area PCA1, a pixel circuit of a second pixel PX2 (FIG. 15) emitting light of a second color may be arranged in the second pixel area PCA2, and a pixel circuit of a third pixel PX3 (FIG. 15) emitting light of a third color may be arranged in the third pixel area PCA3. According to an embodiment, the first pixel PX1 may be a red pixel emitting red light, the second pixel PX2 may be a green pixel emitting green light, and the third pixel PX3 may be a blue pixel emitting blue light. Hereinafter, FIGS. 6 to 16 are described by referring to FIG. 17 together.

Referring to FIG. 6, a buffer layer 101 may be arranged on the substrate 100 (FIG. 17), and a semiconductor layer ACT may be located on the buffer layer 101. The semiconductor layer ACT may include amorphous silicon, polycrystalline silicon, or an organic semiconductor material, such as an oxide semiconductor. The semiconductor layer ACT may include a first semiconductor layer ACTa and a second semiconductor layer ACTb.

The first semiconductor layer ACTa may have various curved shapes in each pixel area. The first semiconductor layer ACTa in each pixel area may include a channel area and a source area and a drain area at both sides of the channel area of each of the first to eighth transistors T1 to T8. The source area or the drain area may also be interpreted as a source electrode or a drain electrode of a transistor, according to embodiments. For example, as illustrated in FIG. 17, a source electrode and a drain electrode of the first transistor T1 may respectively correspond to a source area S1 and a drain area D1 doped with impurities around the channel area A1.

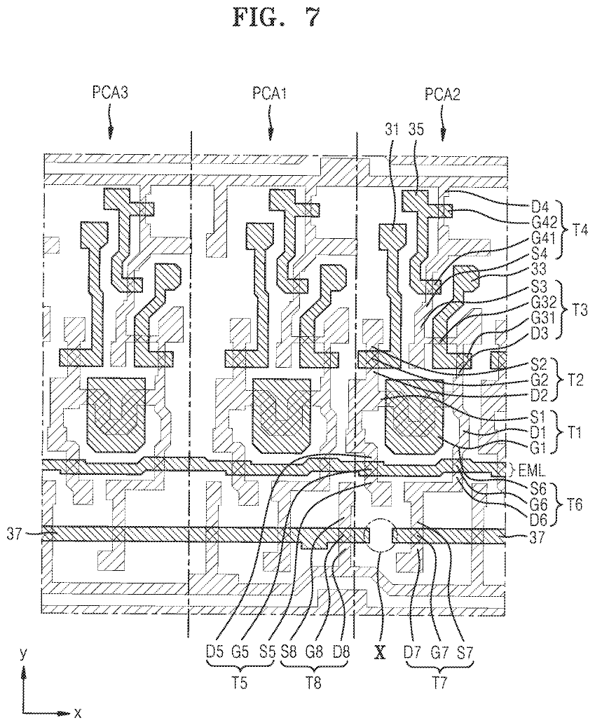

Referring to FIG. 7, the first semiconductor layer ACTa in each pixel area may include a source area S1 and a drain area D1 of the first transistor T1, a source area S2 and a drain area D2 of the second transistor T2, a source area S3 and a drain area D3 of the third transistor T3, a source area S4 and a drain area D4 of the fourth transistor T4, a source area S5 and a drain area D5 of the fifth transistor T5, a source area S6 and a drain area D6 of the sixth transistor T6, a source area S7 and a drain area D7 of the seventh transistor T7, and a source area S8 and a drain area D8 of the eighth transistor T8. The first semiconductor layer ACTa may include a channel area between the source area and the drain area of each of the first to eighth transistors T1 to T8.

The first semiconductor layer ACTa in each pixel area may include a protrusion portion 25 protruding from a middle area between the source area S3 and the drain area D3 of the third transistor T3 and a protrusion portion 27 protruding from a middle area between the source area S4 and the drain area D4 of the fourth transistor T4. The first semiconductor layer ACTa may include a first extension line 21 crossing the pixel areas in a row and extending in the x direction. The first semiconductor layer ACTa of each of the first pixel area PCA1, the second pixel area PCA2, and the third pixel area PCA3 may be connected to each other by the first extension line 21. The first semiconductor layer ACTa may include a protrusion portion 22 protruding from the first extension line 21 in the y direction.

The second semiconductor layer ACTb may include a second extension line 23 crossing the pixel areas in a row and extending in the x direction and a protrusion portion 24 protruding from the second extension line 23 in the y direction. The protrusion portion 24 may be included in one of the pixel areas in the unit pixel area PCAu, for example, the protrusion portion 24 may be included only in the first pixel area PCA1. The first extension line 21 and the second extension line 23 may be shared by the pixel circuits arranged in the pixel areas in the row.

A first insulating layer 111 may be located above the semiconductor layer ACT.

As illustrated in FIG. 7, gate electrodes G1 to G8 of the first to eighth transistors T1 to T8 may be arranged on the first insulating layer 111. The emission control line EML may be arranged on the first insulating layer 111 to extend in the x direction, wherein the emission control line EML may include the same material and may be arranged on the same layer as the gate electrodes G1 to G8 of the first to eighth transistors T1 to T8.

The gate electrodes G1 to G8 of the first to eighth transistors T1 to T8 may overlap the channel areas of the first semiconductor layer ACTa. The gate electrode G1 of the first transistor T1 may be provided as an island type. The gate electrode G2 of the second transistor T2 may be a portion of a conductive pattern 31, the portion crossing the first semiconductor layer ACTa. Gate electrodes G31 and G32 of the third transistor T3 may be portions of a conductive pattern 33, the portions crossing the first semiconductor layer ACTa. Gate electrodes G41 and G42 of the fourth transistor T4 may be portions of a conductive pattern 35, the portions crossing the first semiconductor layer ACTa. The gate electrode G5 of the fifth transistor T5 and the gate electrode G6 of the sixth transistor T6 may be portions of the emission control line EML, the portions crossing the first semiconductor layer ACTa. The gate electrode G7 of the seventh transistor T7 and the gate electrode G8 of the eighth transistor T8 may be portions of a conductive pattern 37, the portions crossing the first semiconductor layer ACTa. The conductive pattern 37 may extend in the x direction and may be shared by the pixel circuits arranged in the pixel areas in the row. According to an embodiment, as illustrated in FIG. 7, the conductive pattern 37 may be disconnected in some pixel areas (for example, region X of the second pixel area PCA2). According to another embodiment, the conductive pattern 37 may extend in the x direction without a disconnection.

The third transistor T3 and the fourth transistor T4 may be dual-gate transistors including two gate electrodes on the same layer. For example, the third transistor T3 may include the sub-transistor T3-1 (FIG. 2B) including the gate electrode G31 and the sub-transistor T3-2 (FIG. 2B) including the gate electrode G32. The fourth transistor T4 may include the sub-transistor T4-1 (FIG. 2B) including the gate electrode G41 and the sub-transistor T4-2 (FIG. 2B) including the gate electrode G42.

The protrusion portion 25 of the first semiconductor layer ACTa may be located between the two gate electrodes G31 and G32 or two channels of the third transistor T3. The protrusion portion 27 of the first semiconductor layer ACTa may be located between the two gate electrodes G41 and G42 or two channels of the fourth transistor T4.

A second insulating layer 112 may be arranged above the gate electrodes G1 to G8 of the first to eighth transistors T1 to T8.

As illustrated in FIG. 8, an electrode voltage line HL, the first initialization voltage line VL1, and the bias voltage line BL may be arranged on the second insulating layer 112 to extend in the x direction.

A portion of the electrode voltage line HL may cover the gate electrode G1 of the first transistor T1. The gate electrode G1 of the first transistor T1 may be a lower electrode C1 of the capacitor Cst. A portion of the electrode voltage line HL may be an upper electrode C2 of the capacitor Cst, which is a second electrode of the capacitor Cst, and may cover the lower electrode C1 of the capacitor Cst. The capacitor Cst may overlap the first transistor T1. The upper electrodes C2 of the capacitors Cst in the pixel areas adjacent to each other may be connected to each other by the electrode voltage line HL. An opening SOP may be formed in the upper electrode C2 of the capacitor Cst.

The first initialization voltage line VL1 may overlap the first extension line 21 of the semiconductor layer ACT.

The bias voltage line BL may overlap the second extension line 23 of the semiconductor layer ACT.

A protrusion portion 45 protruding from the electrode voltage line HL in the y direction may overlap the protrusion portions 25 and 27 of the first semiconductor layer ACTa. The protrusion portion 25 of the first semiconductor layer ACTa and a portion of the protrusion portion 45, the portion overlapping the protrusion portion 25, may respectively form a lower electrode C3 and an upper electrode C4 of the second capacitor Ch1. The protrusion portion 27 of the first semiconductor layer ACTa and a portion of the protrusion portion 45, the portion overlapping the protrusion portion 27, may respectively form a lower electrode C5 and an upper electrode C6 of the third capacitor Ch2.

The electrode voltage line HL may be connected to a first driving voltage line PL1 to be described below, and thus, the upper electrode C4 of the second capacitor Ch1 and the upper electrode C6 of the third capacitor Ch2 may receive a driving voltage ELVDD. The second capacitor Ch1 may be arranged between the third transistor T3 and the driving voltage line PL, and the third capacitor Ch2 may be arranged between the fourth transistor T4 and the driving voltage line PL. The second capacitor Ch1 may be arranged between the driving voltage line PL and a region between the pair of sub-transistors T3-1 and T3-2 of the third transistor T3. The third capacitor Ch2 may be arranged between the driving voltage line PL and a region between the pair of sub-transistors T4-1 and T4-2 of the fourth transistor T4. Due to the second capacitor Ch1 and the third capacitor Ch2, off-current leakage of the third transistor T3 and the fourth transistor T4 may be reduced, and there may be improvement in terms of a flicker phenomenon as illustrated in FIG. 4B.

A repair line RL may further be arranged on the second insulating layer 112. The repair line RL may overlap a region between the sixth transistor T6 and the seventh transistor T7 of the first semiconductor layer ACTa. The repair line RL may be connected to the organic light-emitting diode OLED separated from the pixel circuit, in case that the pixel circuit is defective.

A third insulating layer 113 may be arranged on the electrode voltage line HL, the first initialization voltage line VL1, and the bias voltage line BL. According to an embodiment, the first insulating layer 111, the second insulating layer 112, and the third insulating layer 113 may be inorganic insulating layers.

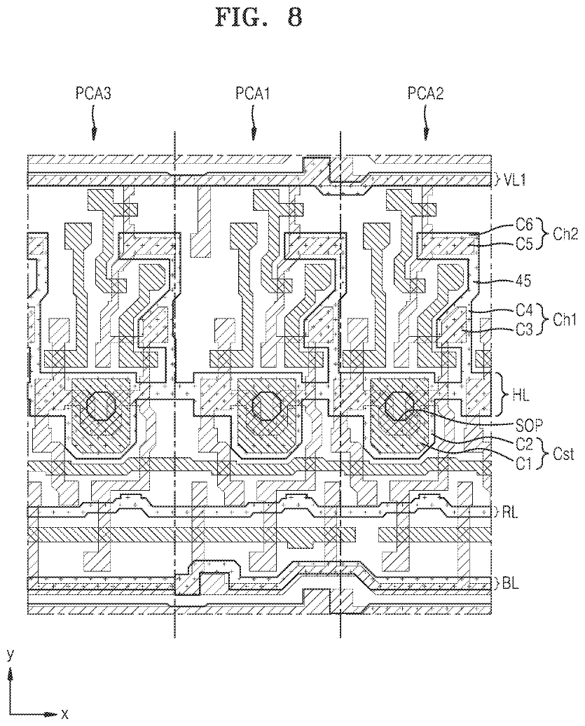

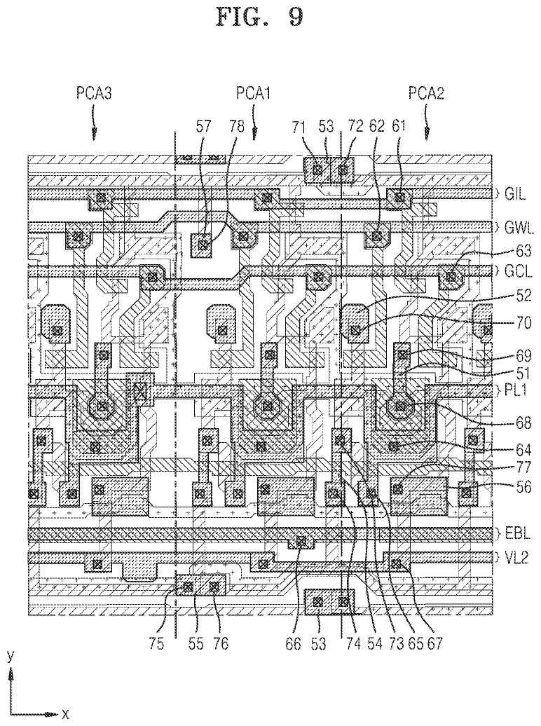

As illustrated in FIG. 9, each of the third gate line GIL, the first gate line GWL, the second gate line GCL, the first driving voltage line PL1, the bias control line EBL, and the second initialization voltage line VL2 may extend on the third insulating layer 113 in the x direction and may be arranged to be apart from each other in the y direction.

The third gate line GIL may be electrically connected to the conductive pattern 35 through a contact hole 61 of the second insulating layer 112 and the third insulating layer 113. The first gate line GWL may be electrically connected to the conductive pattern 31 through a contact hole 62 of the second insulating layer 112 and the third insulating layer 113. The second gate line GCL may be electrically connected to the conductive pattern 33 through a contact hole 63 of the second insulating layer 112 and the third insulating layer 113.

The first driving voltage line PL1 may overlap the electrode voltage line HL, may be electrically connected to the electrode voltage line HL through a contact hole 64 of the third insulating layer 113, and may be electrically connected to the source area S5 of the fifth transistor T5 through a contact hole 65 formed in the first insulating layer 111, the second insulating layer 112, and the third insulating layer 113.

The bias control line EBL may overlap the conductive pattern 37 and may be electrically connected to the conductive pattern 37 through a contact hole 66 of the third insulating layer 113.

The second initialization voltage line VL2 may be electrically connected to the drain area D7 of the seventh transistor T7 through a contact hole 67 formed in the first insulating layer 111, the second insulating layer 112, and the third insulating layer 113.

A node electrode 51 and conductive patterns 52, 53, 54, 55, 56, and 57 may further be arranged on the third insulating layer 113. The node electrode 51 may electrically connect the gate electrode G1 of the first transistor T1 with the third transistor T3 through an opening SOP of the upper electrode C2 of the capacitor Cst. An end of the node electrode 51 may be electrically connected to the gate electrode G1 of the first transistor T1 through a contact hole 68 penetrating the second insulating layer 112 and the third insulating layer 113. The other end of the node electrode 51 may be electrically connected to the source area S3 of the third transistor T3 and the source area S4 of the fourth transistor T4 through a contact hole 69 penetrating the first insulating layer 111, the second insulating layer 112, and the third insulating layer 113.

The conductive pattern 52 may be electrically connected to the source area S2 of the second transistor T2 through a contact hole 70 penetrating the first insulating layer 111, the second insulating layer 112, and the third insulating layer 113. The conductive pattern 53 may be electrically connected to the first initialization voltage line VL1 through a contact hole 71 penetrating the second insulating layer 112 and the third insulating layer 113 and may be electrically connected to the first extension line 21 of the first semiconductor layer ACTa through a contact hole 72 penetrating the first insulating layer 111, the second insulating layer 112, and the third insulating layer 113. The conductive pattern 54 may be electrically connected to the drain area D5 of the fifth transistor T5 through a contact hole 73 penetrating the first insulating layer 111, the second insulating layer 112, and the third insulating layer 113 and may be electrically connected to the protrusion portion 24 of the second extension line 23 of the second semiconductor layer ACTb through a contact hole 74 penetrating the first insulating layer 111, the second insulating layer 112, and the third insulating layer 113. The conductive pattern 55 may be electrically connected to the bias voltage line BL through a contact hole 75 penetrating the second insulating layer 112 and the third insulating layer 113 and may be electrically connected to the second extension line 23 of the second semiconductor layer ACTb through a contact hole 76 penetrating the first insulating layer 111, the second insulating layer 112, and the third insulating layer 113. The conductive pattern 56 may be electrically connected to the drain area D6 of the sixth transistor T6 and the source area S7 of the seventh transistor T7 through a contact hole 77 penetrating the first insulating layer 111, the second insulating layer 112, and the third insulating layer 113. The conductive pattern 57 may be electrically connected to the protrusion portion 22 (FIG. 6) of the first extension line 21 of the first semiconductor layer ACTa through a contact hole 78 penetrating the first insulating layer 111, the second insulating layer 112, and the third insulating layer 113.

The conductive patterns 53, 55, and 57 may be provided in one of the pixel areas in the unit pixel area PCAu, for example, may be provided only in the first pixel area PCA1.

A fourth insulating layer 114 may be arranged on the third gate line GIL, the first gate line GWL, the second gate line GCL, the first driving voltage line PL1, the bias control line EBL, and the second initialization voltage line VL2.

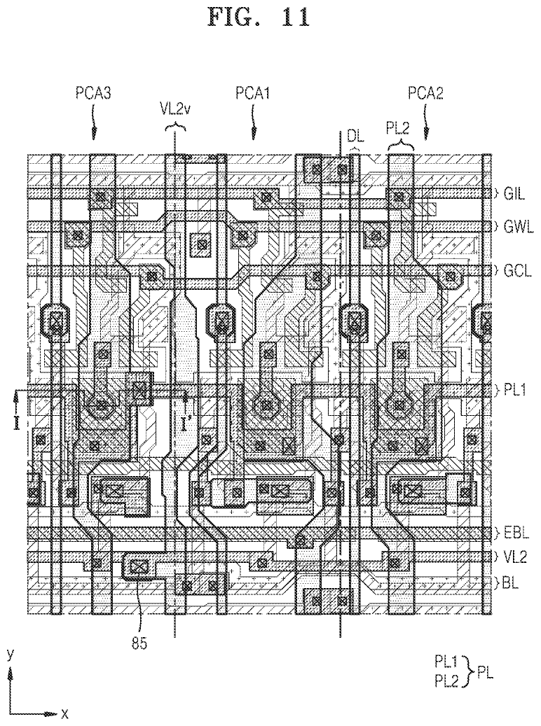

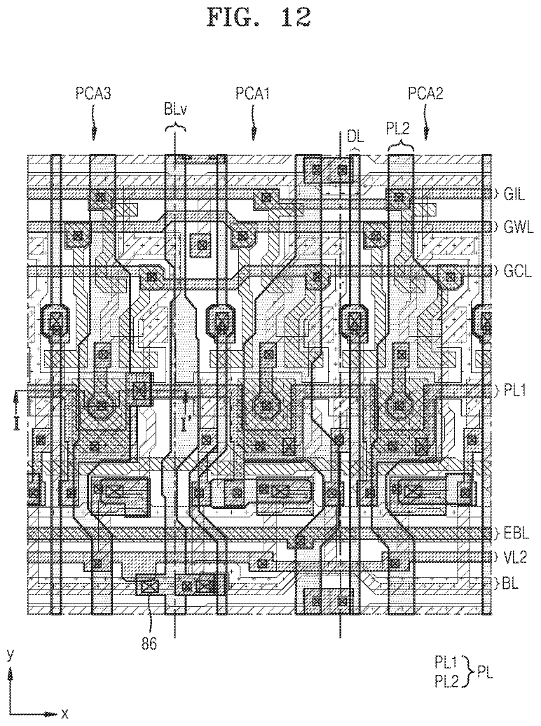

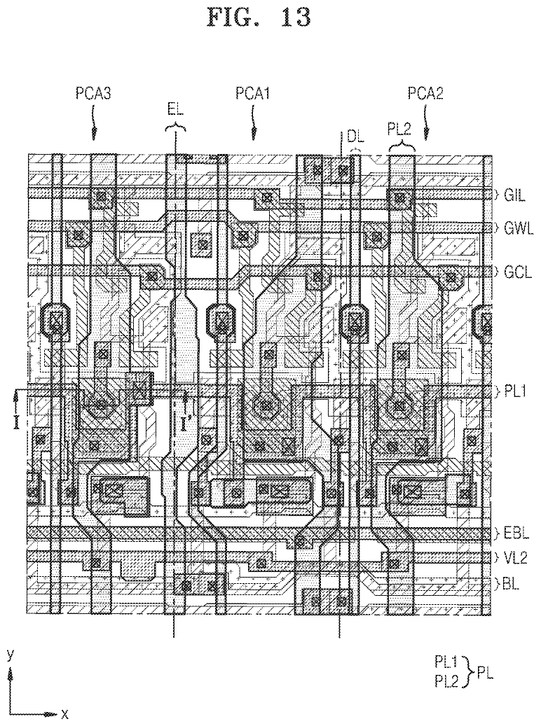

As illustrated in FIGS. 10 to 13, the data line DL, the second driving voltage line PL2, and vertical conductive lines VTL (FIG. 17) may extend on the fourth insulating layer 114 in the y direction and may be arranged to be apart from each other in the x direction. The vertical conductive lines VTL may include the first vertical initialization voltage line VL1v illustrated in FIG. 10, the second vertical initialization voltage line VL2v illustrated in FIG. 11, the vertical bias voltage line BLv illustrated in FIG. 12, and the common voltage line EL illustrated in FIG. 13. The vertical conductive lines VTL may be arranged between the first pixel area PCA1 and the third pixel area PCA3.

The data line DL may be arranged in each pixel area for each column. The data line DL may be electrically connected to the conductive pattern 52 through a contact hole 81 of the fourth insulating layer 114 to be connected to the source area S2 of the second transistor T2.

The second driving voltage line PL2 may be arranged in each pixel area for each column. The second driving voltage line PL2 may be electrically connected to the first driving voltage line PL1 through a contact hole 82 of the fourth insulating layer 114. The driving voltage line PL may include the first driving voltage line PL1 in the x direction and the second driving voltage line PL2 in the y direction to have a mesh structure in the display area DA.

The first vertical initialization voltage line VL1v illustrated in FIG. 10 may be electrically connected to the conductive pattern 57 through a contact hole 84 of the fourth insulating layer 114 to be electrically connected to the first initialization voltage line VL1, and thus, the first initialization voltage line VL1 may have a mesh structure in the display area DA.

The second vertical initialization voltage line VL2v illustrated in FIG. 11 may be electrically connected to the second initialization voltage line VL2 through a contact hole 85 of the fourth insulating layer 114, and thus, the second initialization voltage line VL2 may have a mesh structure in the display area DA.

The vertical bias voltage line BLv illustrated in FIG. 12 may be electrically connected to the bias voltage line BL through a contact hole 86 of the fourth insulating layer 114, and thus, the bias voltage line BL may have a mesh structure in the display area DA.

A conductive pattern 91 may further be arranged on the fourth insulating layer 114. The conductive pattern 91 may be electrically connected to the conductive pattern 56 through a contact hole 83 of the fourth insulating layer 114.

Referring to FIG. 17, a fifth insulating layer 115 may be arranged on the vertical conductive lines VTL. The organic light-emitting diode OLED as a display element may be arranged on the fifth insulating layer 115. The organic light-emitting diode OLED may include a pixel electrode 201, an opposite electrode 205, and an intermediate layer 203 between the pixel electrode 201 and the opposite electrode 205.

The fourth insulating layer 114 and the fifth insulating layer 115 may be organic insulating layers.

As illustrated in FIG. 14, the pixel electrode 201 arranged on the fifth insulating layer 115 may be electrically connected to the conductive pattern 91 therebelow through a contact hole 95 (FIG. 10) of the fifth insulating layer 115 so that the pixel electrode 201 may be connected to the first transistor T1 through the sixth transistor T6.

According to an embodiment, the pixel electrode 201 connected to the pixel circuit of the first pixel PX1 arranged in the first pixel area PCA1 and the pixel electrode 201 connected to the pixel circuit of the third pixel PX3 arranged in the third pixel area PCA3 may overlap the pixel circuit of the third pixel area PCA3, may each have a square shape, and may be arranged to be adjacent to each other in the y direction. The pixel electrode 201 connected to the pixel circuit of the second pixel PX2 arranged in the second pixel area PCA2 may overlap the pixel circuit of the first pixel area PCA1 and the pixel circuit of the second pixel area PCA2 and may have a “ [symbol] ” shape. The pixel electrode 201 connected to the pixel circuit of the second pixel PX2 may include a first portion 201a having a first width 201W1 in the x direction and a second portion 201b having a second width 201W2 in the x direction. A pair of second portions 201b extending from the first portion 201a and protruding may face each other with a groove therebetween. The second width 201W2 may be less than the first width 201W1. A pixel-defining layer 116 covering an edge of the pixel electrode 201 may be arranged above the pixel electrode 201. An opening 1160P exposing a portion of the pixel electrode 201 and defining an emission area may be defined in the pixel-defining layer 116. The pixel-defining layer 116 may be a single organic insulating layer or organic insulating layers and/or a single inorganic insulating layer or inorganic insulating layers.

The intermediate layer 203 may include an emission layer, and a first functional layer above the emission layer and/or a second functional layer below the emission layer. The first functional layer may be a hole transport layer (HTL). In an embodiment, the first functional layer may include a hole injection layer (HIL) and an HTL. The second functional layer may include an electron transport layer ETL and/or an electron injection layer EIL. The first functional layer and the second functional layer may be integrally formed to correspond to the organic light-emitting diodes OLEDs included in the display area DA. The first functional layer or the second functional layer may be omitted.

The opposite electrode 205 may be integrally formed to correspond to the organic light-emitting diodes OLEDs included in the display area DA.

FIG. 15 is a schematic diagram illustrating arrangement of emission areas of pixels, according to an embodiment.

Referring to FIG. 15, the pixels arranged in the display area DA may include a first pixel PX1, a second pixel PX2, and a third pixel PX3. The first pixel PX1, the second pixel PX2, and the third pixel PX3 may be repeatedly arranged in a pattern (e.g., a predetermined or selectable pattern) in the x direction and the y direction. Each of the first pixel PX1, the second pixel PX2, and the third pixel PX3 may include a pixel circuit and an organic light-emitting diode OLED electrically connected to the pixel circuit. The organic light-emitting diode OLED of each pixel may be arranged above the pixel circuit. The organic light-emitting diode OLED may be arranged above (e.g., directly above) the pixel circuit to overlap the pixel circuit or may be arranged to be offset with respect to the pixel circuit to partially overlap the pixel circuit of another pixel arranged in an adjacent row and/or an adjacent column.

FIG. 15 illustrates an emission area of each of the first to third pixels PX1 to PX3. The emission area may be an area where an emission layer of the organic light-emitting diode OLED is arranged. The emission area may be defined by an opening of the pixel-defining layer, as illustrated in FIG. 17. Because the emission layer is arranged on the pixel electrode, the arrangement of the emission areas illustrated in FIG. 15 may indicate arrangement of the pixel electrodes or arrangement of the pixels.

As illustrated in FIG. 15, an emission area EA1 of the first pixel PX1 and an emission area EA3 of the third pixel PX3 may be adjacent to each other in the y direction, and an emission area EA2 of the second pixel PX2 may be arranged to be adjacent to the emission area EA1 of the first pixel PX1 and the emission area EA3 of the third pixel PX3 in the x direction. Accordingly, the emission area EA1 of the first pixel PX1 and the emission area EA3 of the third pixel PX3 may be alternately arranged with each other in the y direction, and the emission area EA2 of the second pixel PX2 may be repeatedly arranged in the y direction.

Length in the x direction and length in the y direction of each of the emission area EA1 of the first pixel PX1, the emission area EA2 of the second pixel PX2, and the emission area EA3 of the third pixel PX3 may be different from each other. For example, the emission area EA1 of the first pixel PX1, the emission area EA2 of the second pixel PX2, and the emission area EA3 of the third pixel PX3 may have quadrangular shapes having long sides in the y direction. A ratio between the length of the emission area EA1 of the first pixel PX1 in the x direction and the length of the emission area EA1 of the first pixel PX1 in the y direction, a ratio between the length of the emission area EA2 of the second pixel PX2 in the x direction and the length of the emission area EA2 of the second pixel PX2 in the y direction, and a ratio between the length of the emission area EA3 of the third pixel PX3 in the x direction and the length of the emission area EA3 of the third pixel PX3 in the y direction may be different from each other. According to another embodiment, the emission area EA1 of the first pixel PX1 and/or the emission area EA3 of the third pixel PX3 may have (a) square shape(s) having the same lengths in the x direction and the y direction. The length of the emission area EA2 of the second pixel PX2 in the y direction may be equal to or greater than a sum of the length of the emission area EA1 of the first pixel PX1 in the y direction and the length of the emission area EA3 of the third pixel PX3 in the y direction. The quadrangular emission area may also include a quadrangular shape having a round corner (vertex).

The emission area EA1 of the first pixel PX1 and the emission area EA3 of the third pixel PX3 may have quadrangular shapes, and the emission area EA2 of the second pixel PX2 may have a “ [symbol] ” shape. A pair of emission areas EA2 of the second pixel PX2 may be arranged such that the “ [symbol] ” shapes face each other.

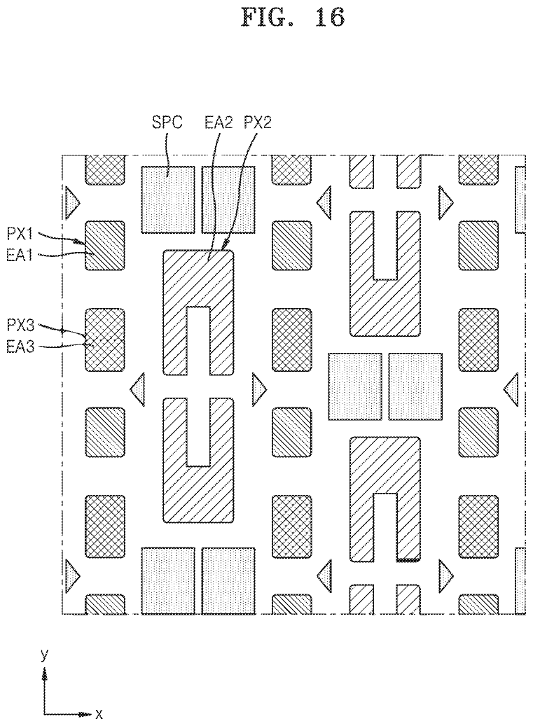

As illustrated in FIG. 16, a spacer SPC may be arranged between the emission areas EA1, EA2, and EA3, according to an embodiment. The spacer SPC may be arranged above the pixel-defining layer 116 at intervals (e.g., predetermined or selectable intervals). FIG. 16 illustrates the spacer SPC having a quadrangular shape, arranged between a pair of emission areas EA2 of the second pixel PX2 and another pair of emission areas EA2 of the second pixel PX2 in the y direction, and the spacer SPC having a triangular shape, arranged between the emission area EA1 of the first pixel PX1 and the emission area EA2 of the second pixel PX2 or between the emission area EA3 of the third pixel PX3 and the emission area EA2 of the second pixel PX2.

The first emission area EA1 of the first pixel PX1, the second emission area EA2 of the second pixel PX2, and the third emission area EA3 of the third pixel PX3 may have different areas (sizes) from each other. According to an embodiment, the emission area EA2 of the second pixel PX2 may have a greater area than the emission area EA1 of the first pixel PX1. The emission area EA2 of the second pixel PX2 may have a greater area than the emission area EA3 of the third pixel PX3. The emission area EA3 of the third pixel PX3 may have a greater area than the emission area EA1 of the first pixel PX1. According to another embodiment, the emission area EA3 of the third pixel PX3 may have the same area as the emission area EA1 of the first pixel PX1.

The emission areas EA1, EA2, and EA3 may have polygonal shapes, such as quadrangular shapes or octagonal shapes, circular shapes, oval shapes, etc., wherein the polygonal shapes may include shapes with round corners (vertexes).

According to an embodiment, the emission areas EA1 to EA3 may be arranged to overlap the pixel areas of the pixels corresponding to the emission areas EA1 to EA3. According to another embodiment, the emission areas EA1 to EA3 may be arranged to overlap the pixel areas of the pixels adjacent to the emission areas EA1 to EA3. FIG. 15 illustrates a pixel arrangement having an S-stripe structure. However, the disclosure is not limited thereto. For example, the pixels may be arranged as a PenTile® matrix structure, a diamond Structure™, a mosaic structure, a delta structure, etc. The pixels may be arranged to have various shapes.

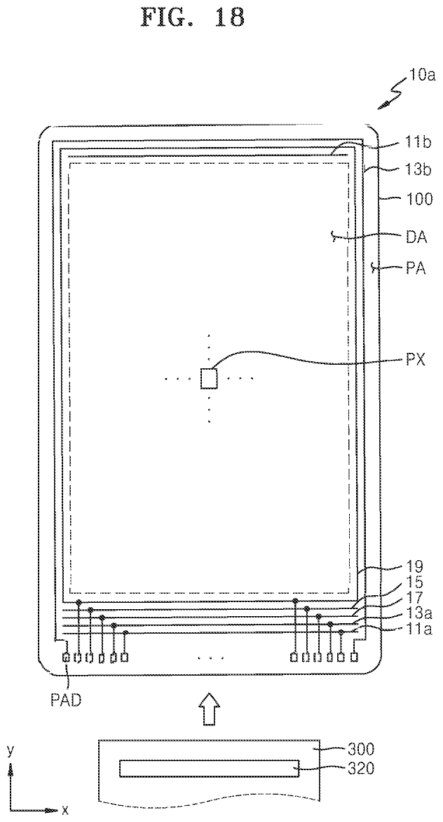

FIG. 18 is a schematic plan view of a display panel 10a according to an embodiment.

The display panel 10a illustrated in FIG. 18 may differ from the display panel 10 illustrated in FIG. 1 in that the display panel 10a has a long side in the second direction (the y direction) and a short side in the first direction (the x direction) in a plan view. A display circuit board 300 on which a display driver 320 is arranged may be connected to a side of the display panel 10a. The display driver 320 may be configured to generate a control signal to be transmitted to a scan driving circuit (not shown) of the peripheral area PA. The display driver 320 may be configured to generate data signals and transmit the data signals to pixel circuits of the display area DA.

A pixel circuit according to an embodiment is not limited to the pixel circuit PC described above. The pixel circuit may be a pixel circuit including the eighth transistor T8, and the number of transistors and capacitors and the connection relationship of the devices may be variously modified.

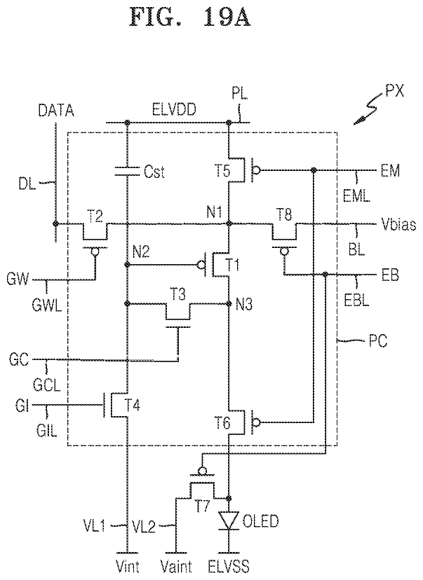

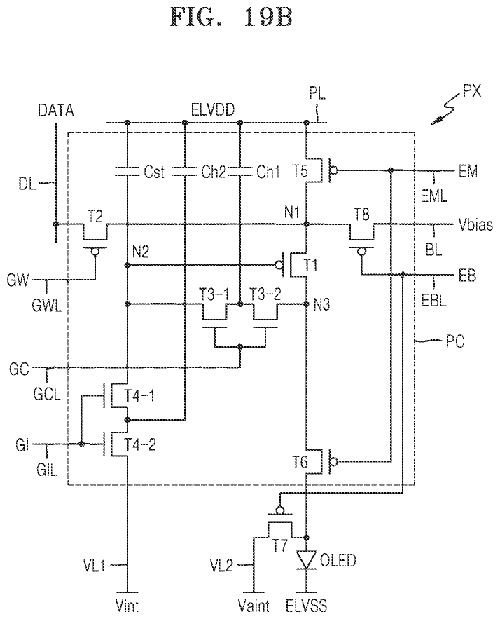

FIGS. 19A and 19B are schematic diagrams of an equivalent circuit of a pixel according to an embodiment.

The pixel circuit PC illustrated in FIGS. 2A and 2B may include the first to eighth transistors T1 to T8 realized as P-channel MOSFETs (PMOS). However, in the pixel circuit PC illustrated in FIGS. 19A and 19B, the third transistor T3 and the fourth transistor T4 from among the first to eighth transistors T1 to T8 may be realized as N-channel MOSFETs (NMOS), and the rest may be realized as the PMOS. Thus, the pixel circuit PC illustrated in FIGS. 19A and 19B may be different from the pixel circuit PC illustrated in FIGS. 2A and 2B, while other configurations may be the same as each other.

In FIG. 19A, the third and fourth transistors T3 and T4 from among the first to eighth transistors T1 to T8 may include a semiconductor layer including an oxide, and the rest may include a semiconductor layer including silicon.

According to another embodiment, as illustrated in FIG. 19B, in the pixel circuit PC, the third transistor T3 may include a pair of sub-transistors T3- and T3-2 connected in series, and the fourth transistor T4 may include a pair of sub-transistors T4-1 and T4-2 connected in series. The pixel circuit PC may further include the second capacitor Ch1 connected between an intermediate node between the sub-transistors T3-1 and T3-2 of the third transistor T3 and the driving voltage line PL and the third capacitor Ch2 connected between an intermediate node between the sub-transistors T4-1 and T4-2 of the fourth transistor T4 and the driving voltage line PL.

According to the embodiments, at least one of the voltage lines connected to the pixel circuit may have a mesh structure in the display area. According to an embodiment, the bias voltage line configured to apply a bias voltage to a terminal of the driving transistor may have a mesh structure. According to an embodiment, the first initialization voltage line configured to apply an initialization voltage to the gate of the driving transistor and the second initialization voltage line configured to apply an initialization voltage to the pixel electrode of the organic light-emitting diode may have a mesh structure. Each of the vertical voltage lines connected to the horizontal bias voltage line, the first initialization voltage line and the second initialization voltage line may be arranged between a pair of pixel areas.

A display apparatus according to the embodiments may be realized as an electronic device, such as a smartphone, a cellular phone, a smart watch, a navigation device, a game machine, a television (TV), a vehicle head unit, a notebook computer, a laptop computer, a tablet computer, a personal media player (PMP), a personal digital assistant (PDA), etc. The electronic device may be a flexible device.

According to the embodiments, at least one of the voltage lines configured to apply a voltage to a pixel circuit configured to drive a display element may have a mesh structure, and thus, a display apparatus having improved display quality may be provided. However, the scope of the disclosure is not limited to this effect as described above.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A display panel comprising:
a driving voltage line;
an organic light-emitting diode;
a driving transistor electrically connected between the driving voltage line and the organic light-emitting diode;
a data write transistor electrically connected between the driving transistor and a data line;
a first voltage line extending in a first direction;
a first transistor electrically connected between the driving transistor and the first voltage line;
a first vertical voltage line extending in a second direction perpendicular to the first direction and electrically connected to the first voltage line; and
a second transistor electrically connected between the driving transistor and the driving voltage line.

2. The display panel of claim 1, wherein
the first transistor is electrically connected between a first node to which the driving transistor and the second transistor are electrically connected and the first voltage line, and
the data write transistor is electrically connected between the first node and the data line.

3. The display panel of claim 1, further comprising:
a second voltage line extending in the first direction;
a third transistor electrically connected between the organic light-emitting diode and the second voltage line; and
a second vertical voltage line extending in the second direction and electrically connected to the second voltage line.

4. The display panel of claim 3, further comprising:
a gate line that applies a control signal to a gate of the first transistor and a gate of the third transistor and extending in the first direction.

5. The display panel of claim 1, further comprising:
a third voltage line extending in the first direction;
a fourth transistor electrically connected between a gate of the driving transistor and the third voltage line; and
a third vertical voltage line extending in the second direction and electrically connected to the third voltage line.

6. The display panel of claim 5, wherein
the fourth transistor comprises a pair of sub-transistors electrically connected in series, and
the display panel further comprises:
a capacitor electrically connected between the driving voltage line and a node between the pair of sub-transistors.

7. The display panel of claim 1, further comprising:
a fifth transistor electrically connected between a gate of the driving transistor and a second node, the second node being between the driving transistor and the organic light-emitting diode.

8. The display panel of claim 7, wherein
the fifth transistor comprises a pair of sub-transistors electrically connected in series, and
the display panel further comprises:
a capacitor electrically connected between the driving voltage line and a node between the pair of sub-transistors.

9. The display panel of claim 1, further comprising:
a fourth transistor electrically connected between a gate of the driving transistor and a third voltage line and comprising a pair of sub-transistors electrically connected in series;
a fifth transistor electrically connected between the gate of the driving transistor and a node, the node being between the driving transistor and the organic light-emitting diode, the fifth transistor comprising a pair of sub-transistors electrically connected in series;
a first capacitor electrically connected between the driving voltage line and the gate of the driving transistor,
a second capacitor electrically connected between the driving voltage line and a node between the pair of sub-transistors of the fourth transistor; and
a third capacitor electrically connected between the driving voltage line and a node between the pair of sub-transistors of the fifth transistor.

10. The display panel of claim 1, wherein the driving voltage line comprises:
a first driving voltage line extending in the first direction; and
a second driving voltage line extending in the second direction and electrically connected to the first driving voltage line.

11. A display panel comprising:
a substrate comprising a display area and a peripheral area surrounding the display area;
a plurality of pixel circuits disposed in pixel areas where rows and columns of pixels in the display area cross each other;
a plurality of first voltage lines extending in a row direction, each of the plurality of first voltage lines being disposed in a corresponding row of the rows; and
a plurality of first vertical voltage lines extending in a column direction, disposed at intervals of a first number of columns, and electrically connected to the plurality of first voltage lines, wherein
each of the plurality of pixel circuits comprises:
a driving transistor,
a data write transistor electrically connected between the driving transistor and a data line;
a first transistor electrically connected between the driving transistor and a first voltage line disposed in a corresponding row from among the plurality of first voltage lines; and
a second transistor electrically connected between the driving transistor and a driving voltage line.

12. The display panel of claim 11, further comprising:
a first voltage supply line disposed in the peripheral area,
wherein the plurality of first voltage lines and the plurality of first vertical voltage lines are electrically connected to the first voltage supply line in the peripheral area.

13. The display panel of claim 11, further comprising:
a plurality of second voltage lines extending in the row direction, each of the plurality of second voltage lines being disposed in a corresponding row of the rows; and
a plurality of second vertical voltage lines extending in the column direction, disposed at intervals of a second number of columns, and electrically connected to the plurality of second voltage lines, wherein
each of the plurality of pixel circuits further comprises:
a third transistor connected between a display element and a second voltage line disposed in a corresponding row from among the plurality of second voltage lines.

14. The display panel of claim 13, further comprising:
a second voltage supply line disposed in the peripheral area,
wherein the plurality of second vertical voltage lines are electrically connected to the second voltage supply line in the peripheral area.

15. The display panel of claim 13, wherein
the first number is greater than the second number,
one of the plurality of first vertical voltage lines is disposed between a pair of adjacent pixel areas, and
one of the plurality of second vertical voltage lines is disposed between another pair of adjacent pixel areas.

16. The display panel of claim 11, further comprising:
a plurality of third voltage lines extending in the row direction, each of the plurality of third voltage lines being disposed in a corresponding row of the rows; and
a plurality of third vertical voltage lines extending in the column direction, disposed at intervals of the first number of columns, and electrically connected to the plurality of third voltage lines,
wherein each of the plurality of pixel circuits further comprises a fourth transistor electrically connected between a gate of the driving transistor and a third voltage line disposed in a corresponding row from among the plurality of third voltage lines.

17. The display panel of claim 16, further comprising:
a third voltage supply line disposed in the peripheral area,
wherein the plurality of third vertical voltage lines are electrically connected to the third voltage supply line in the peripheral area.

18. The display panel of claim 16, wherein
one of the plurality of first vertical voltage lines is disposed between a pair of adjacent pixel areas, and
one of the plurality of third vertical voltage lines is disposed between another pair of adjacent pixel areas.

19. The display panel of claim 16, wherein each of the pixel circuits comprises:
a fifth transistor electrically connected between the gate of the driving transistor and a second node, the second node being between the driving transistor and an organic light-emitting diode;
a first capacitor comprising a first electrode including the gate of the driving transistor and a second electrode above the first electrode;
a second capacitor comprising a third electrode electrically connected to a semiconductor layer of the fifth transistor and a fourth electrode above the third electrode; and
a third capacitor comprising a fifth electrode electrically connected to a semiconductor layer of the fourth transistor and a sixth electrode above the fifth electrode.

20. The display panel of claim 19, wherein
the third electrode of the second capacitor and the fifth electrode of the third capacitor each include a semiconductor material, and
the second electrode of the first capacitor, the fourth electrode of the second capacitor, and the sixth electrode of the third capacitor are integral with each other and electrically connected to the driving voltage line.
